(19) United States
(12) Patent Application Publication
(10) Pub. No.: US 2016/0182083 A1
(43) Pub. Date: Jun. 23, 2016

(54) Systems and Methods for Decoder Scheduling With Overlap and/or Switch Limiting

(71) Applicant: Avago Technologies General IP (Singapore) Pte. Ltd., Singapore (SG)

(72) Inventors: Shu Li, San Jose, CA (US); Shaohua Yang, San Jose, CA (US)

(21) Appl. No.: 14/582,104

(22) Filed: Dec. 23, 2014

(51) Int. Cl. H03M 7/16; H03M 13/11

(52) U.S. Cl. CPC H03M 7/16; H03M 13/1171

(57) ABSTRACT

The present inventions are related to systems and methods for data processing, and more particularly to systems and methods for scheduling in a data decoder.

### FIELD OF THE INVENTION

The present inventions are related to systems and methods for data processing, and more particularly to systems and methods for scheduling in a data decoder.

### BACKGROUND

Various data storage systems have been developed that include data decoding circuitry. Such data decoding circuitry generally schedules the processing of elements of a decoded message based upon a first in, first out scheduling. In some cases, such an approach to scheduling can use significant power and/or require processing delays to facilitate the first in, first out ordering.

Hence, for at least the aforementioned reasons, there exists a need in the art for advanced systems and methods for scheduling operations in a data processing system.

### SUMMARY

The present inventions are related to systems and methods for data processing, and more particularly to systems and methods for scheduling in a data decoder.

Some embodiments of the present invention provide systems for decoding a data set. The systems include a data decoder circuit that is configured to apply a data decoding algorithm to a data input to yield a decoded output. The operation of the data decoder circuit is governed at least in part by a modified H-matrix. The modified H-matrix enforces a column processing order that eliminates dependencies between columns at the beginning of the column processing order and columns at the ending of the column processing order. In some cases, the data decoder circuit implements a low density parity check decoding algorithm.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment or one embodiment, and may be included in more than one embodiment. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a storage device including switch and/or delay limiting data decoder scheduling circuitry in accordance with various embodiments;

FIG. 2 depicts a data transmission device including a receiver having switch and/or delay limiting data decoder scheduling circuitry in accordance with one or more embodiments;

FIG. 3 shows a solid state memory circuit including a data processing circuit having switch and/or delay limiting data decoder scheduling circuitry in accordance with some embodiments;

FIG. 4 depicts another data processing system including a having local iteration overlap and/or switch limiting data decoder scheduling circuitry in accordance with various embodiments;

FIGS. 5a-5b show an example local iteration based element re-ordering in accordance with some embodiments;

FIG. 6 is a flow diagram showing a method in accordance with some embodiments for local iteration overlap limiting;

FIGS. 7a-7j shows an example element re-ordering in accordance with some embodiments;

FIG. 8 is a flow diagram showing a method in accordance with one or more embodiments for switch limiting during application of a data decoding algorithm; and

FIG. 9 is a flow diagram showing a method in accordance with various embodiments of the present invention for a combination of switch limiting and local iteration overlap limiting.

### DETAILED DESCRIPTION OF SOME EMBODIMENTS

The present inventions are related to systems and methods for data processing, and more particularly to systems and methods for synchronizing operations in a data storage system.

Some embodiments of the present invention provide systems for decoding a data set. The systems include a data decoder circuit that is configured to apply a data decoding algorithm to a data input to yield a decoded output. The operation of the data decoder circuit is governed at least in part by a modified H-matrix. The modified H-matrix enforces a column processing order that eliminates dependencies between columns at the beginning of the column processing order and columns at the ending of the column processing order. In some cases, the data decoder circuit implements a low density parity check decoding algorithm.

In some instances of the aforementioned embodiments, a subsequent local iteration through the data decoder circuit begins before completion of a preceding local iteration through the data decoder circuit. In some cases, the preceding local iteration is performing minimum calculations to yield minimums and minimum locations for a first set of elements while the succeeding local iteration is calculating check node to variable node messages based upon the minimums and minimum locations for a second set of locations. In one or more instances of the aforementioned embodiments, the modified H-matrix further enforces a processing order conforming to a Gray code pattern where the Gray code pattern is represented as the row dependencies in each of the columns.

In various instances of the aforementioned embodiments, the system is implemented as part of a storage device or a communication device. In some cases, the system is implemented as part of an integrated circuit. In one or more instances of the aforementioned embodiments, the modified H-matrix includes columns of circulants in an order that reduces switching between rows in the modified H-matrix.

Other embodiments of the present invention provide systems for decoding a data set that include a data decoder circuit operable to apply a data decoding algorithm to a data input to yield a decoded output. Operation of the data decoder circuit is governed at least in part by a modified H-matrix. The modified H-matrix enforces a column processing order that processes H-matrix columns in an order according to column row dependencies. In some instances of the aforementioned embodiments, the column row dependencies include at least a first set of column row dependencies, a second set of column row dependencies, a third set of column row dependencies, and a fourth set of column row dependencies; and wherein the column processing order includes: processing all columns exhibiting the first set of column row dependencies before processing all columns exhibiting the second set of column row dependencies, processing all columns exhibiting the second set of column row dependencies before processing all columns exhibiting the third set of column row dependencies, and processing all columns exhibiting the third set of column row dependencies before processing all columns exhibiting the fourth set of column row dependencies. In some such instances, switching from rows in the first set of column row dependencies and the second set of column row dependencies, from rows in the second set of column row dependencies and the third set of column row dependencies, from rows in the third set of column row dependencies and the fourth set of column row dependencies, and from rows in the third set of column row dependencies and the fourth set of column row dependencies corresponds to a Gray code pattern of the rows. In some cases, the Gray code pattern of the rows limits switching between rows of the modified H-matrix during application of the data decoding algorithm. Such limiting of switching between rows during application of the data decoding algorithm reduces power consumption by the data decoder circuit.

In one or more instances of the aforementioned embodiments, the modified H-matrix further enforces a column processing order that eliminates dependencies between columns at the beginning of the column processing order and columns at the ending of the column processing order.

Other embodiments of the present invention provide methods for decoding a data set that include: providing a data decoder circuit operable to apply a data decoding algorithm to a data input to yield a decoded output; and applying the data decoding algorithm guided by a modified H-matrix where the modified H-matrix enforces a column processing order that eliminates dependencies between columns at the beginning of the column processing order and columns at the ending of the column processing order. In some instances of the aforementioned embodiments, the modified H-matrix further enforces a column processing order that processes H-matrix columns in an order according to column row dependencies.

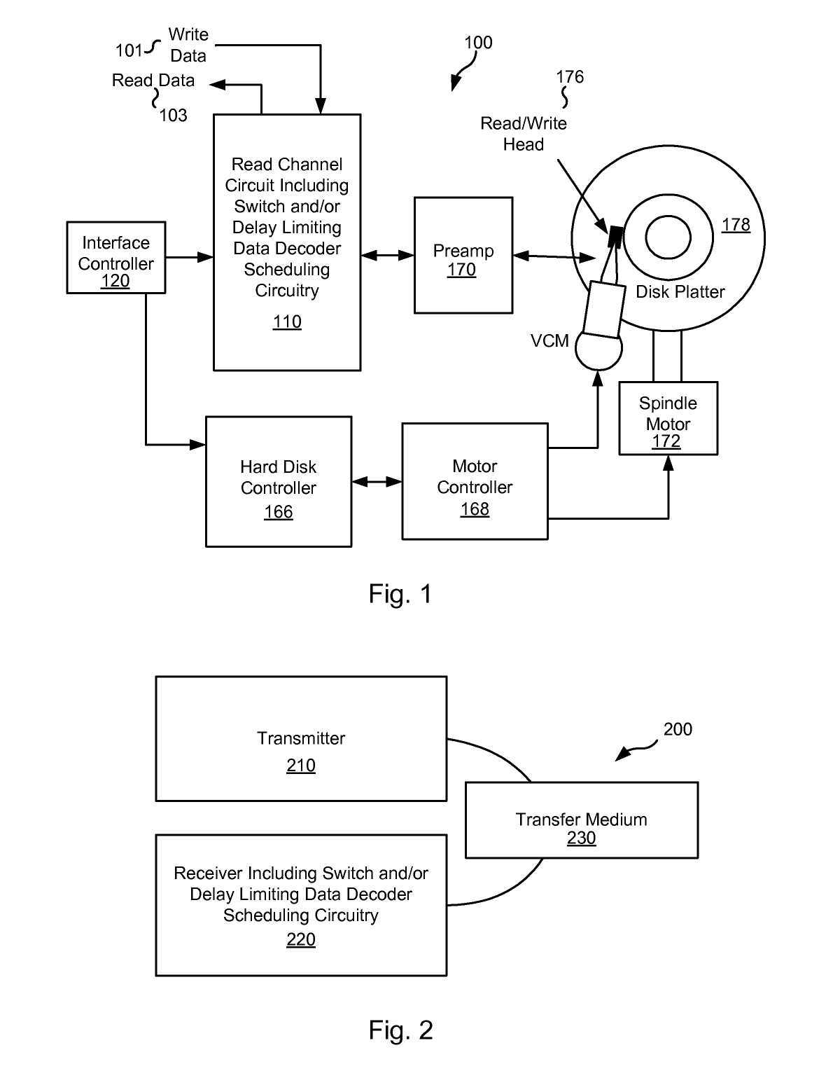

Turning to FIG. 1, a storage system 100 is shown that includes a read channel circuit 110 including switch and/or delay limiting data decoder scheduling circuitry in accordance with various embodiments. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head 176. Interface controller 120 controls addressing and timing of data to/from disk platter 178, and interacts with a host controller (not shown). The data on disk platter 178 consists of groups of magnetic signals that may be detected by read/write head assembly 176 when the assembly is properly positioned over disk platter 178. In one embodiment, disk platter 178 includes magnetic signals recorded in accordance with either a longitudinal or a perpendicular recording scheme.

In a typical read operation, read/write head 176 is accurately positioned by motor controller 168 over a desired data track on disk platter 178. Motor controller 168 both positions read/write head 176 in relation to disk platter 178 and drives spindle motor 172 by moving read/write head assembly 176 to the proper data track on disk platter 178 under the direction of hard disk controller 166. Spindle motor 172 spins disk platter 178 at a determined spin rate (RPMs). Once read/write head 176 is positioned adjacent the proper data track, magnetic signals representing data on disk platter 178 are sensed by read/write head 176 as disk platter 178 is rotated by spindle motor 172. The sensed magnetic signals are provided as a continuous, minute analog signal representative of the magnetic data on disk platter 178. This minute analog signal is transferred from read/write head 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. This data is provided as read data 103 to a receiving circuit. A write operation is substantially the opposite of the preceding read operation with write data 101 being provided to read channel circuit 110. This data is then encoded and written to disk platter 178.

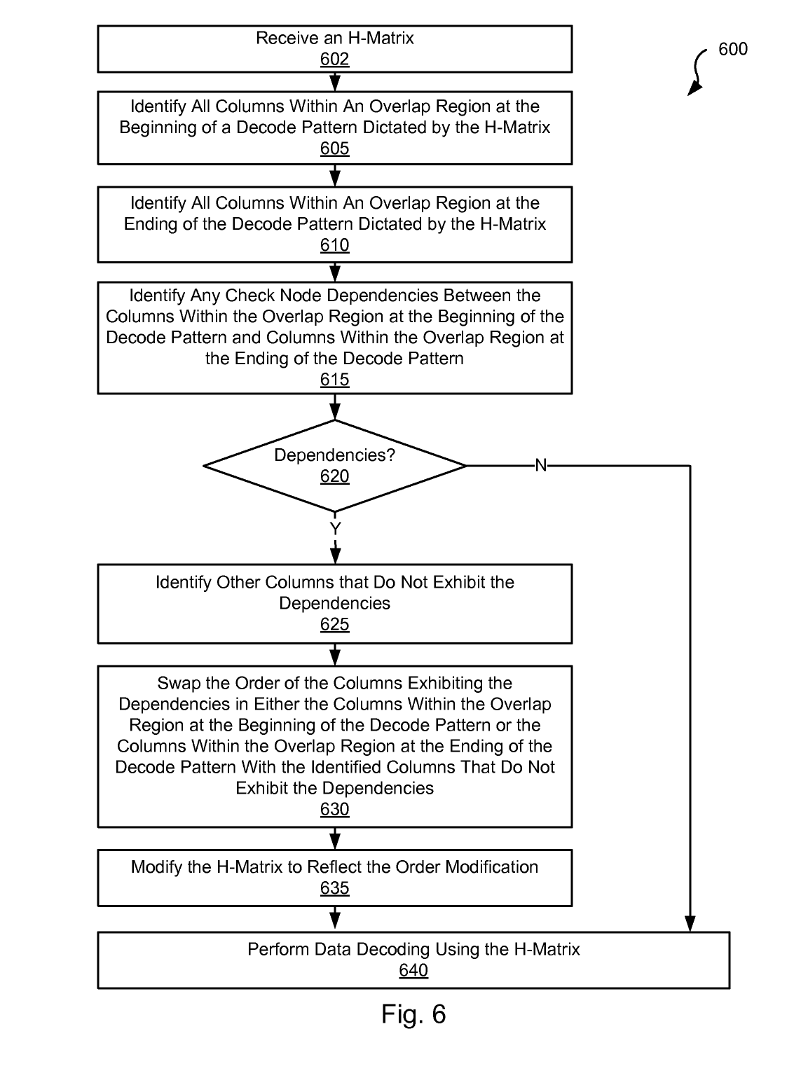

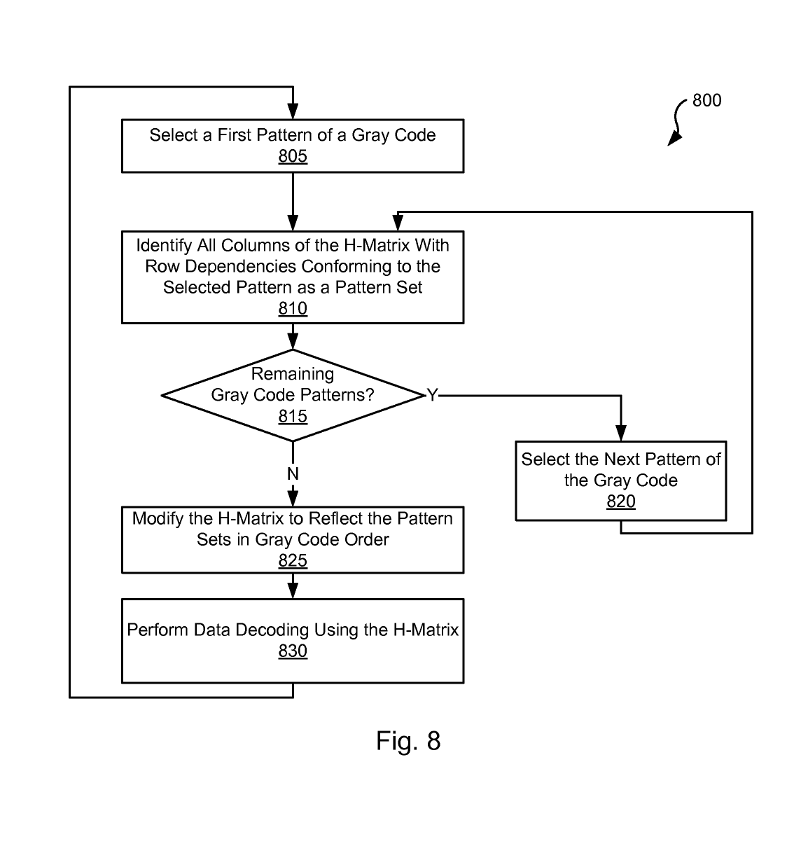

In operation, data accessed from disk platter 178 is processed using a decoding algorithm guided by an H-matrix that is modified to reduce local iteration overlap and/or limiting switching between rows of the H-matrix. The overlap reduction reduces the need to insert delay cycles to allow for resolution of a preceding local iteration before the beginning of a subsequent local iteration. The switch limiting reduces an overall power consumption by read channel circuit 110. The data processing may be implemented similar to that discussed below in relation to FIG. 4. Further, the data processing may be completed using a method such as that discussed in relation to FIGS. 6, 8 and/or 9.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platted 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

Turning to FIG. 2, a data transmission system 200 including a receiver 220 having switch and/or delay limiting data decoder scheduling circuitry in accordance with one or more embodiments. A transmitter 210 transmits encoded data via a transfer medium 230 as is known in the art. The encoded data is received from transfer medium 230 by receiver 220.

In operation, data received via transfer medium 230 is processed by receiver 220 using a decoding algorithm guided by an H-matrix that is modified to reduce local iteration overlap and/or limiting switching between rows of the H-matrix. The overlap reduction reduces the need to insert delay cycles to allow for resolution of a preceding local iteration before the beginning of a subsequent local iteration. The switch limiting reduces an overall power consumption by read channel circuit 110. The data processing may be implemented similar to that discussed below in relation to FIG. 4. Further, the data processing may be completed using a method such as that discussed in relation to FIGS. 6, 8 and/or 9.

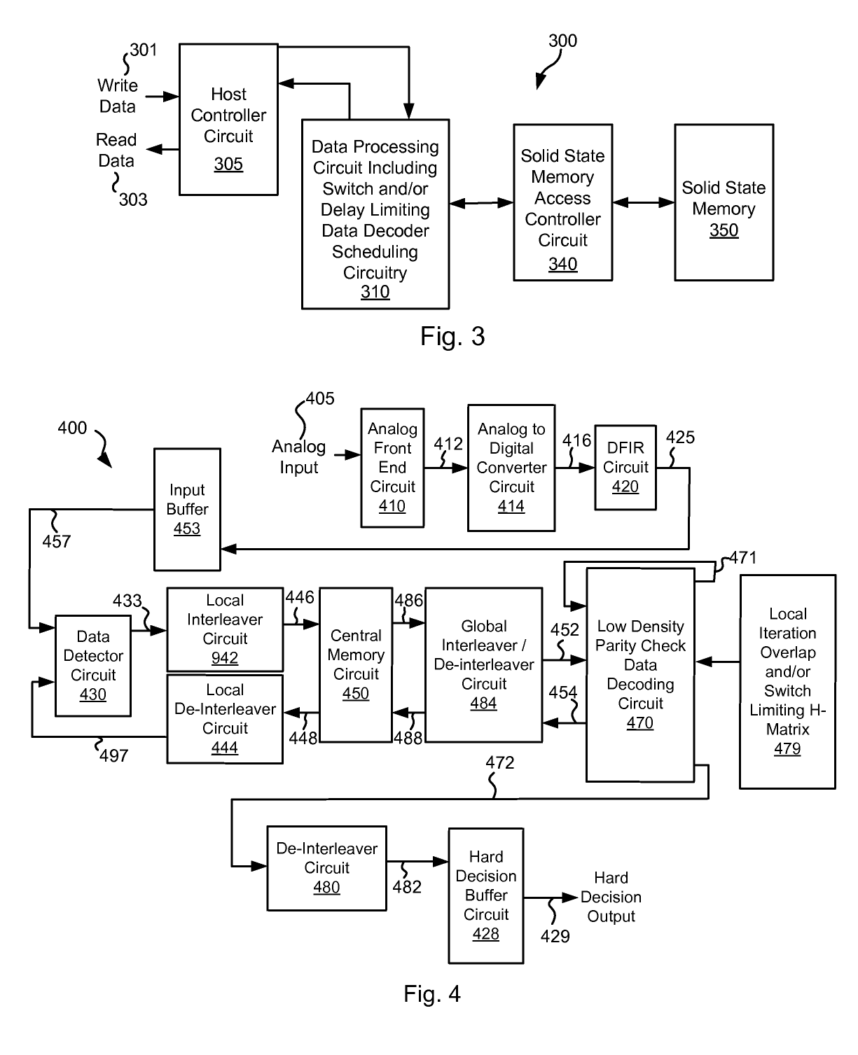

Turning to FIG. 3, another storage system 300 is shown that includes a data processing circuit 310 having switch and/or delay limiting data decoder scheduling circuitry in accordance with some embodiments. A host controller circuit 305 receives data to be stored (i.e., write data 301). Solid state memory access controller circuit 340 may be any circuit known in the art that is capable of controlling access to and from a solid state memory. Solid state memory access controller circuit 340 formats the received encoded data for transfer to a solid state memory 350. Solid state memory 350 may be any solid state memory known in the art. In some embodiments, solid state memory 350 is a flash memory. Later, when the previously written data is to be accessed from solid state memory 350, solid state memory access controller circuit 340 requests the data from solid state memory 350 and provides the requested data to data processing circuit 310. In turn, data processing circuit 310 processes the requested data using a decoding algorithm guided by an H-matrix that is modified to reduce local iteration overlap and/or limiting switching between rows of the H-matrix. The overlap reduction reduces the need to insert delay cycles to allow for resolution of a preceding local iteration before the beginning of a subsequent local iteration. The switch limiting reduces an overall power consumption by read channel circuit 110. The data processing may be implemented similar to that discussed below in relation to FIG. 4. Further, the data processing may be completed using a method such as that discussed in relation to FIGS. 6, 8 and/or 9.

Turning to FIG. 4, another data processing system 400 including local iteration overlap and/or switch limiting data decoder scheduling circuitry is shown in accordance with various embodiments. Data processing system 400 includes an analog front end circuit 410 that receives an analog signal 405. Analog front end circuit 410 processes analog signal 405 and provides a processed analog signal 412 to an analog to digital converter circuit 414. Analog front end circuit 410 may include, but is not limited to, an analog filter and an amplifier circuit as are known in the art. Based upon the disclosure provided herein, one of ordinary skill in the art will recognize a variety of circuitry that may be included as part of analog front end circuit 410. In some cases, analog signal 405 is derived from a read/write head assembly (not shown) that is disposed in relation to a storage medium (not shown). In other cases, analog signal 405 is derived from a receiver circuit (not shown) that is operable to receive a signal from a transmission medium (not shown). The transmission medium may be wired or wireless. Based upon the disclosure provided herein, one of ordinary skill in the art will recognize a variety of source from which analog input 405 may be derived.

Analog to digital converter circuit 414 converts processed analog signal 412 into a corresponding series of digital samples 416. Analog to digital converter circuit 414 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments. Digital samples 416 are provided to an equalizer circuit 420. Equalizer circuit 420 applies an equalization algorithm to digital samples 416 to yield an equalized output 425. In some embodiments, equalizer circuit 420 is a digital finite impulse response filter circuit as are known in the art. It may be possible that equalized output 425 may be received directly from a storage device in, for example, a solid state storage system. In such cases, analog front end circuit 410, analog to digital converter circuit 414 and equalizer circuit 420 may be eliminated where the data is received as a digital data input. Equalized output 425 is stored to an input buffer 453 that includes sufficient memory to maintain a number of codewords until processing of that codeword is completed through a data detector circuit 430 and low density parity check (LDPC) decoding circuit 470 including, where warranted, multiple global iterations (passes through both data detector circuit 430 and LDPC decoding circuit 470) and/or local iterations (passes through LDPC decoding circuit 470 during a given global iteration). An output 457 is provided to data detector circuit 430.

Data detector circuit 430 may be a single data detector circuit or may be two or more data detector circuits operating in parallel on different codewords. Whether it is a single data detector circuit or a number of data detector circuits operating in parallel, data detector circuit 430 is operable to apply a data detection algorithm to a received codeword or data set. In some embodiments, data detector circuit 430 is a Viterbi algorithm data detector circuit as are known in the art. In other embodiments, data detector circuit 430 is a maximum a posteriori data detector circuit as are known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments. In some cases, one data detector circuit included in data detector circuit 430 is used to apply the data detection algorithm to the received codeword for a first global iteration applied to the received codeword, and another data detector circuit included in data detector circuit 430 is operable apply the data detection algorithm to the received codeword guided by a decoded output accessed from a central memory circuit 450 on subsequent global iterations.

Upon completion of application of the data detection algorithm to the received codeword on the first global iteration, data detector circuit 430 provides a detector output 433. Detector output 433 includes soft data. As used herein, the phrase “soft data” is used in its broadest sense to mean reliability data with each instance of the reliability data indicating a likelihood that a corresponding bit position or group of bit positions has been correctly detected. In some embodiments, the soft data or reliability data is log likelihood ratio data as is known in the art. Detector output 433 is provided to a local interleaver circuit 442. Local interleaver circuit 442 is operable to shuffle sub-portions (i.e., local chunks) of the data set included as detected output and provides an interleaved codeword 446 that is stored to central memory circuit 450. Local interleaver circuit 442 may be any circuit known in the art that is capable of shuffling data sets to yield a re-arranged data set. Interleaved codeword 446 is stored to central memory circuit 450.

Once LDPC decoding circuit 470 is available, a previously stored interleaved codeword 446 is accessed from central memory circuit 450 as a stored codeword 486 and globally interleaved by a global interleaver/de-interleaver circuit 484. Global interleaver/de-interleaver circuit 484 may be any circuit known in the art that is capable of globally rearranging codewords. Global interleaver/De-interleaver circuit 484 provides a decoder input 452 into LDPC decoding circuit 470. LDPC decoding circuit 470 applies one or more local iterations of a data decoding algorithm (either layered or non-layered) to decoder input 452 to yield a decoded output 471. In cases where another local iteration (i.e., another pass through LDPC decoding circuit 470) is desired (i.e., decoding failed to converge and more local iterations are allowed), LDPC decoding circuit 470 re-applies the data decoding algorithm to decoder input 452 guided by decoded output 471. This continues until either a maximum number of local iterations is exceeded or decoded output 471 converges (i.e., completion of standard processing).

In one embodiment, an H-matrix 479 guides LDPC decoding circuit 470. H-matrix 479 is modified to limit local iteration overlap and/or switching. The modification of H-matrix 479 includes identifying columns in an unmodified H-matrix within an overlap region at the beginning of a decode pattern dictated by the H-matrix, and columns within an overlap region at the ending of a decode pattern. The columns within the overlap region at the beginning of the decode pattern are the columns of the H-matrix that will begin processing by data decoding circuit 470 on a subsequent local iteration before data decoding circuit 470 has completed processing of the preceding local iteration. In prior operations, delay cycles were inserted to delay processing of the subsequent local iteration to assure that any dependencies of the subsequent local iteration are resolved before the preceding local iteration is completed. In particular, a preceding iteration may be calculating minimums (min1, min2) and a minimum location for elements that may be used early in a succeeding local iteration. By adding delay periods, completion of calculating minimums is assured before the results of the calculations are needed for a subsequent local iteration. However, such insertion of delay cycles is wasteful. The number of columns of succeeding local iterations that overlap is known, and the amount of overlap is referred to as an overlap region. The columns at the ending of the decode pattern are those that will still be processing for a preceding local iteration when the columns at the beginning of the decode pattern begin processing on the subsequent iteration. The columns still processing from the preceding local iteration while columns of the succeeding local iteration begin processing are within the overlap region.

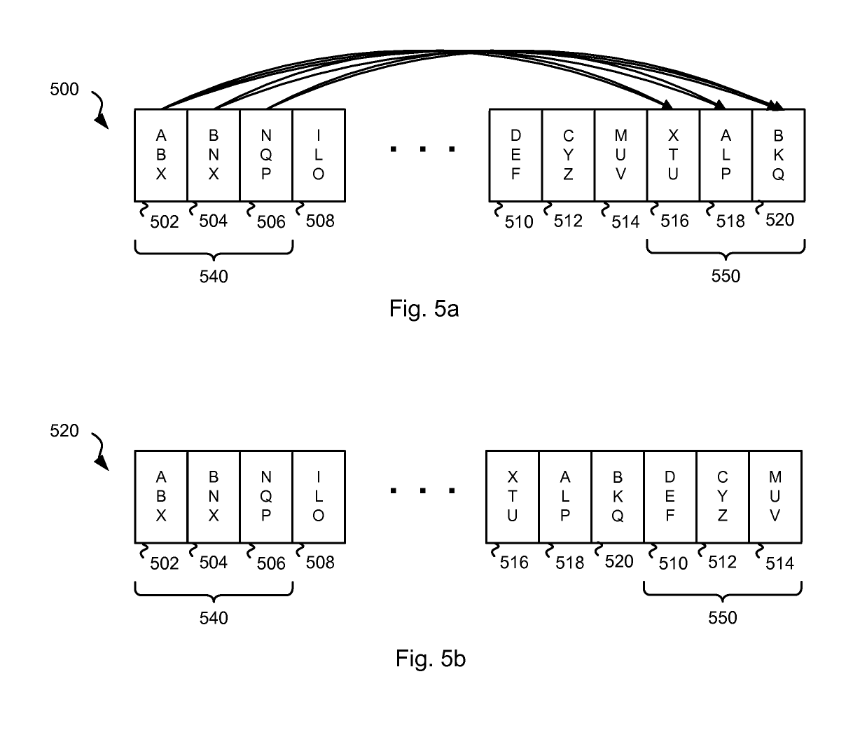

Turning to FIG. 5a, a series of columns (i.e., columns 502, 504, 506, 508, 510, 512, 514, 516, 518, 520) of an unmodified H-matrix 500 dictating the processing order of a data decoding algorithm are shown. As shown, column 502 is dependent upon the results for rows A, B and X; column 504 is dependent upon the results for rows B, N and X; column 506 is dependent upon the results for rows N, Q and P; column 508 is dependent upon the results for rows I, L and O; column 510 is dependent upon the results for rows D, E and F; column 512 is dependent upon the results for rows C, Y and Z; column 514 is dependent upon the results for rows M, U and V; column 516 is dependent upon the results for rows X, T and U; column 518 is dependent upon the results for rows A, L and P; and column 520 is dependent upon the results for rows B, K and Q. An overlap region 540 at the beginning of a decode pattern includes columns 502, 504, 506; and an overlap region 550 at the ending of a decode pattern includes columns 516, 518, 520. It should be noted that while an overlap of three columns between succeeding local iterations is shown in FIG. 5a, that more or fewer columns may overlap.

As shown in FIG. 5a, processing of column 502 cannot begin in a subsequent local iteration as processing of columns 516, 518 and 520 each impact the same rows processed by column 502 (i.e., row X of columns 502, 516; row A of columns 502, 518; and row B of columns 502, 520). Similarly, processing of column 504 cannot begin in a subsequent local iteration as processing of columns 516 and 520 each impact the same rows processed by column 504 (i.e., row X of columns 504, 516; and row B of columns 504, 520); and processing of column 506 cannot begin in a subsequent local iteration as processing of columns 518 and 520 each impact the same rows processed by column 506 (i.e., row P of columns 506, 518; and row Q of columns 506, 520). Thus, without modifying H-matrix 500, delay cycles sufficient to complete processing of columns 516, 518, 520 must be used to assure that all of the dependencies are resolved.

Where no dependencies exist between the respective overlap regions, H-matrix 479 is not modified. On the other hand, where dependencies exist, other columns that do not exhibit dependencies are identified. Using FIG. 5a again as an example, none of columns 502, 504, 506 are dependent upon any of columns 512, 514, 516. Accordingly, columns 512, 514, 516 may be chosen as not exhibiting dependencies. The order of the columns exhibiting the aforementioned dependencies are swapped such that non-dependent columns are used to replace either the columns in the overlap region at the ending or the columns in the overlap region at the beginning. Thus, using FIG. 5a again as an example, the order of column processing may be modified such that columns 510, 512 and 514 are processed after columns 516, 518, 520. This change is processing order is shown in FIG. 5b where a modified H-matrix 520 is shown, and where overlap region 550 at the ending of a decode pattern now includes columns 516, 518, 520. By making this modification, delay cycles are no longer required to assure proper processing by data decoding circuit 470 as the dependencies on the results from calculating minimums in a preceding local iteration are moved farther into the processing (i.e., beyond the overlap regions) such that completion of calculating the minimums is assured without requiring insertion of delay periods.

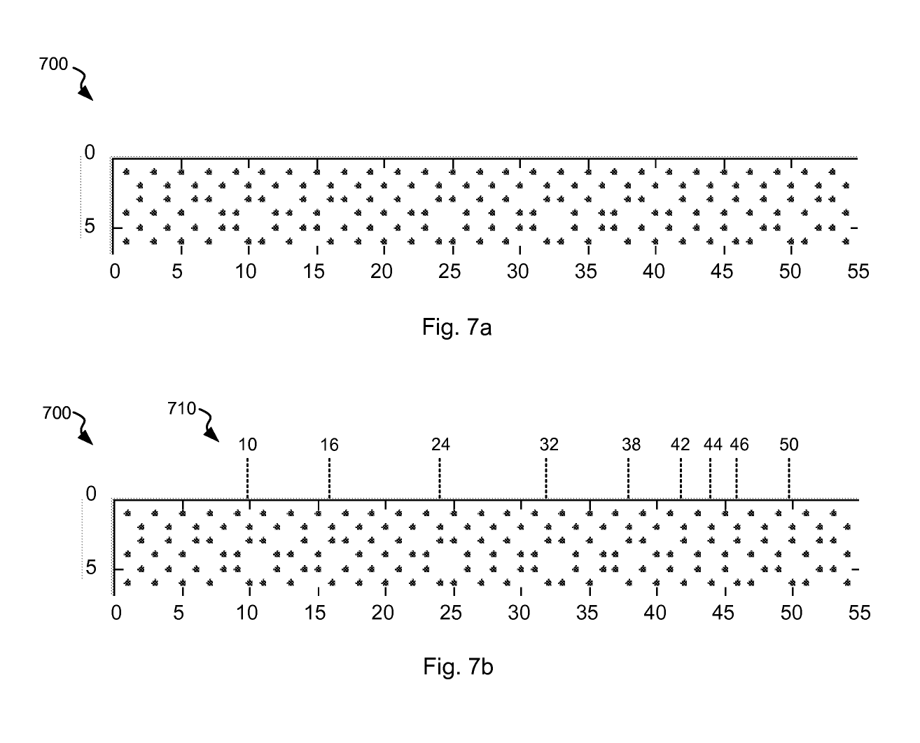

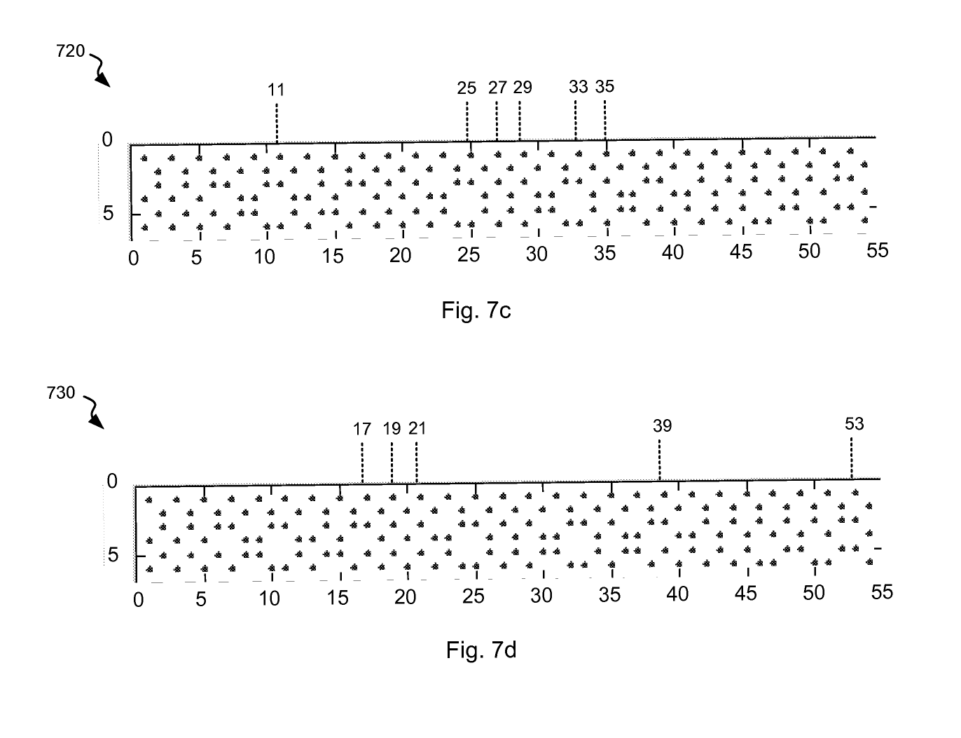

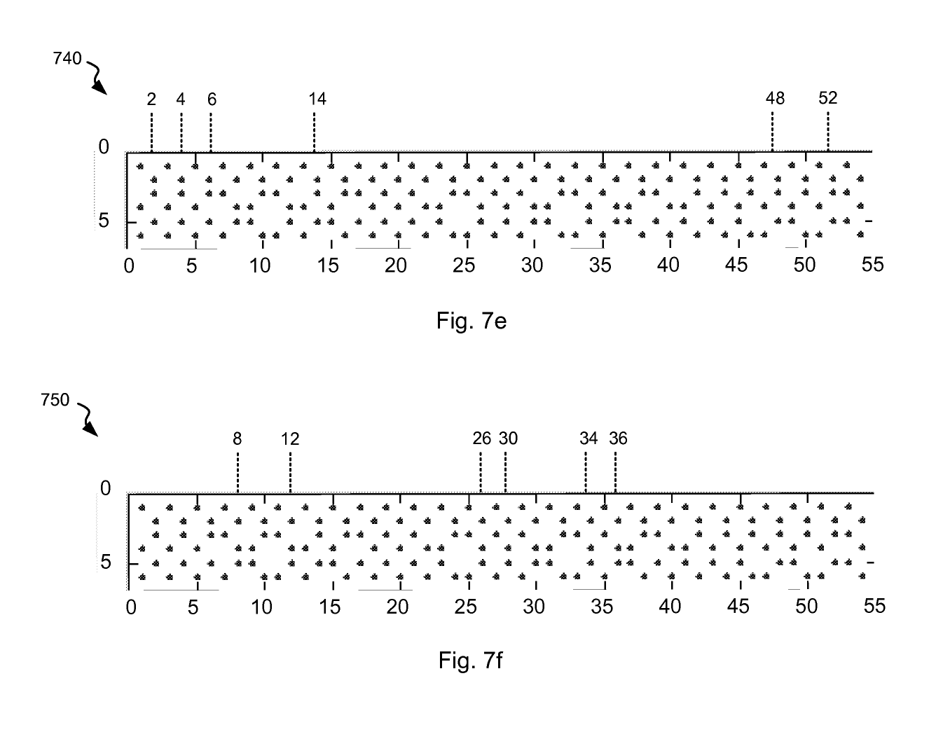

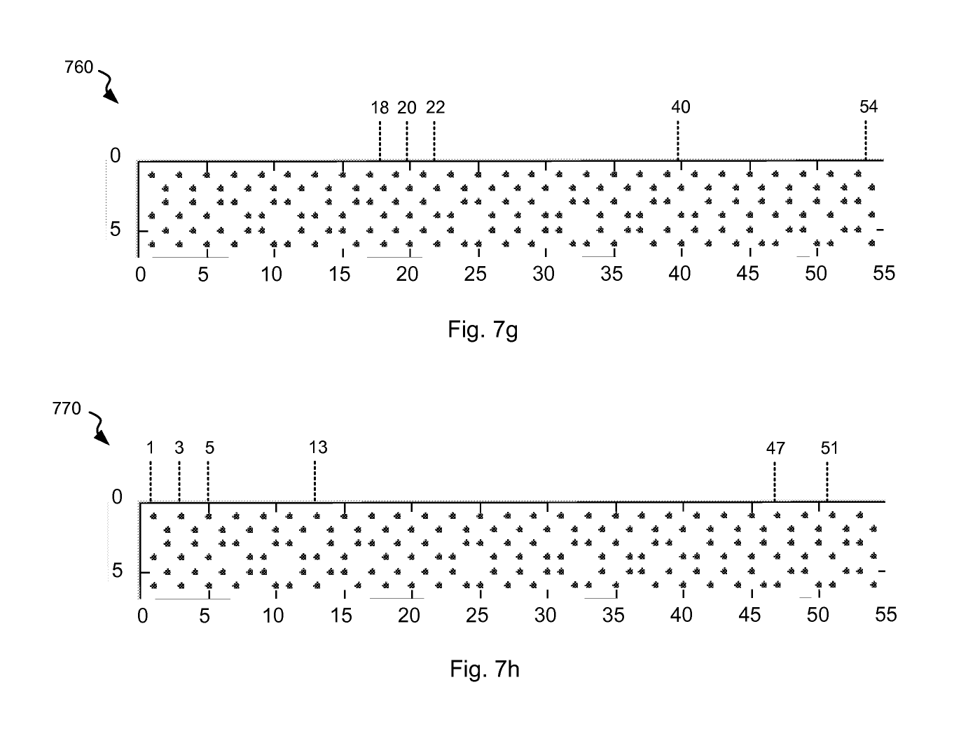

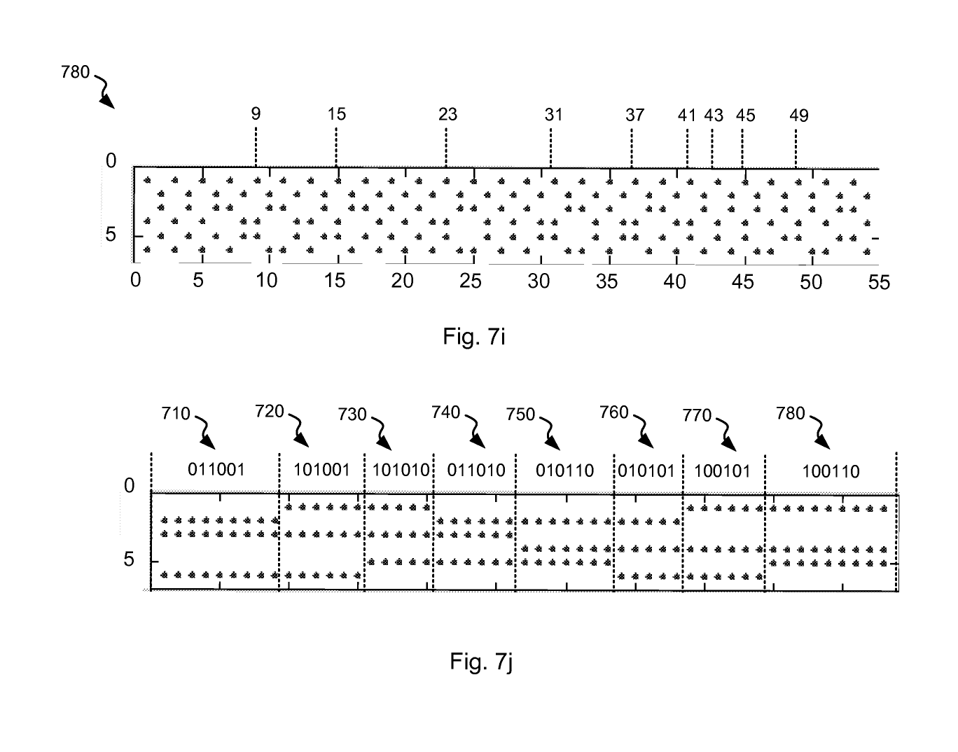

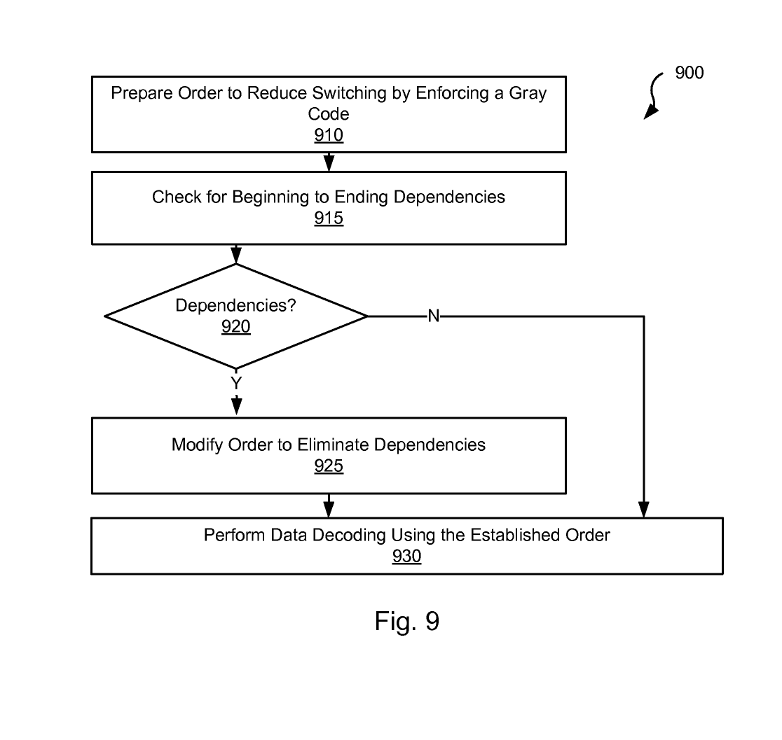

Additionally, the H-matrix may be modified to arrange columns of the H-matrix in an order that causes them to process in accordance with a Gray code pattern where the Gray code pattern corresponds to rows within the H-matrix. Turning to FIG. 7a, a pattern 700 of elements is shown where the columns of an unmodified H-matrix each rely on different rows (i.e., rows 1-6 on the left side) are included in the same columns (i.e., columns 1-55 along the bottom). Thus, as an example, elements from rows 1, 4 and 6 are connected for the elements of column 1. The rows 1, 4 and 6 corresponds to a Gray code pattern ‘100101’. Each column includes a number of connections that correspond to a given Gray code pattern. Turning to FIG. 7b as an example, a Gray code pattern 710 ('011001′) is selected and all columns corresponding to this pattern are identified. Columns 710 corresponding to Gray code pattern ‘011001’ include a pattern set 710 (i.e., columns 10, 16, 24, 32, 38, 42, 44, 46, 50). Turning to FIG. 7c, as an example, a pattern set 720 corresponding to a next Gray code pattern ‘101001’ is selected and all columns corresponding to this pattern are identified. Of note, a minimum number of rows changes in the next pattern. In this case, the prior Gray code pattern ‘011001’ is changed to the next Gray code pattern ‘101001’, resulting in a change to only the first two rows. Turning to FIG. 7d, as an example, a pattern set 730 corresponding to a next Gray code pattern ‘101010’ is selected and all columns corresponding to this pattern are identified. Of note, a minimum number of rows changes in the next pattern. In this case, the prior Gray code pattern ‘101001’ is changed to the next Gray code pattern ‘101010’, resulting in a change to only the last two rows. Turning to FIG. 7e, as an example, a pattern set 740 corresponding to a next Gray code pattern ‘011010’ is selected and all columns corresponding to this pattern are identified. Of note, a minimum number of rows changes in the next pattern. In this case, the prior Gray code pattern ‘101010’ is changed to the next Gray code pattern ‘011010’, resulting in a change to only the first two rows. Turning to FIG. 7f, as an example, a pattern set 750 corresponding to a next Gray code pattern ‘010110’ is selected and all columns corresponding to this pattern are identified. Of note, a minimum number of rows changes in the next pattern. In this case, the prior Gray code pattern ‘011010’ is changed to the next Gray code pattern ‘010110’, resulting in a change to only the middle two rows. Turning to FIG. 7g, as an example, a pattern set 760 corresponding to a next Gray code pattern ‘010101’ is selected and all columns corresponding to this pattern are identified. Of note, a minimum number of rows changes in the next pattern. In this case, the prior Gray code pattern ‘010110’ is changed to the next Gray code pattern ‘010101’, resulting in a change to only the last two rows. Turning to FIG. 7h, as an example, a pattern set 770 corresponding to a next Gray code pattern ‘100101’ is selected and all columns corresponding to this pattern are identified. Of note, a minimum number of rows changes in the next pattern. In this case, the prior Gray code pattern ‘010101’ is changed to the next Gray code pattern ‘100101’, resulting in a change to only the first two rows. Turning to FIG. 7i, as an example, a pattern set 780 corresponding to a next Gray code pattern ‘100110’ is selected and all columns corresponding to this pattern are identified. Of note, a minimum number of rows changes in the next pattern. In this case, the prior Gray code pattern ‘100101’ is changed to the next Gray code pattern ‘100110’, resulting in a change to only the last two rows. Ultimately, the H-matrix arranged as in FIG. 7j with the respective pattern sets (i.e., pattern sets 710-780) arranged in Gray code order to reduce row switching is use to control the data decoding applied by LDPC data decoding circuit 470. It should be noted that the H-matrix may be modified to accommodate both end overlap and row switching as discussed below in relation to FIG. 9.

Where decoded output 471 fails to converge (i.e., fails to yield the originally written data set) and a number of local iterations through LDPC decoding circuit 470 exceeds a threshold, but an allowable number of global iterations is not yet exceeded, the resulting decoded output is provided as a decoded output 454 back to central memory circuit 450 where it is stored awaiting another global iteration through a data detector circuit included in data detector circuit 430. Prior to storage of decoded output 454 to central memory circuit 450, decoded output 454 is globally de-interleaved to yield a globally de-interleaved output 488 that is stored to central memory circuit 450. The global de-interleaving reverses the global interleaving earlier applied to stored codeword 486 to yield decoder input 452. When a data detector circuit included in data detector circuit 430 becomes available, a previously stored de-interleaved output 488 is accessed from central memory circuit 450 and locally de-interleaved by a de-interleaver circuit 444. De-interleaver circuit 444 re-arranges decoder output 448 to reverse the shuffling originally performed by interleaver circuit 442. A resulting de-interleaved output 497 is provided to data detector circuit 430 where it is used to guide subsequent detection of a corresponding data set previously received as equalized output 425.

Alternatively, where the decoded output converges (i.e., yields the originally written data set), the resulting decoded output is provided as an output codeword 472 to a de-interleaver circuit 480 that rearranges the data to reverse both the global and local interleaving applied to the data to yield a de-interleaved output 482. De-interleaved output 482 is provided to a hard decision buffer circuit 428 buffers de-interleaved output 482 as it is transferred to the requesting host as a hard decision output 429.

As yet another alternative, where decoded output 471 fails to converge (i.e., fails to yield the originally written data set), a number of local iterations through LDPC decoding circuit 470 exceeds a threshold, and a number of global iterations through data detector circuit 430 and LDPC data decoding circuit 470 exceeds a threshold, the result of the last pass through LDPC decoding circuit 470 is provided as a decoded output along with an error indicator (not shown).

Turning to FIG. 6, a flow diagram 600 shows a method in accordance with some embodiments for local iteration overlap limiting. Following flow diagram 600, an unmodified H-matrix is received (block 602). Such an H-matrix is designed to govern application of a data decoding algorithm. Columns in the H-matrix within an overlap region at the beginning of a decode pattern dictated by the H-matrix are identified (block 605). These identified columns are the columns of the H-matrix that will begin processing by a data decoder circuit on a subsequent local iteration before the data decoder circuit has completed processing of the preceding local iteration. In prior operations delay cycles were inserted to delay processing of the subsequent local iteration to assure that any dependencies of the subsequent local iteration were resolved before the preceding local iteration completed. Such insertion of delay cycles is wasteful. The number of columns of succeeding local iterations that overlap is known, and the amount of overlap is the aforementioned overlap region. Columns in the H-matrix within an overlap region at the ending of a decode pattern dictated by the H-matrix are identified (block 610). The columns at the ending of the decode pattern are those that will still be processing for a preceding local iteration when the columns at the beginning of the decode pattern begin processing on the subsequent iteration. Any dependencies between the respective overlap regions are identified (block 615).

Turning to FIG. 5a, a series of columns (i.e., columns 502, 504, 506, 508, 510, 512, 514, 516, 518, 520) of an unmodified H-matrix 500 dictating the processing order of a data decoding algorithm are shown. As shown, column 502 is dependent upon the results for rows A, B and X; column 504 is dependent upon the results for rows B, N and X; column 506 is dependent upon the results for rows N, Q and P; column 508 is dependent upon the results for rows I, L and O; column 510 is dependent upon the results for rows D, E and F; column 512 is dependent upon the results for rows C, Y and Z; column 514 is dependent upon the results for rows M, U and V; column 516 is dependent upon the results for rows X, T and U; column 518 is dependent upon the results for rows A, L and P; and column 520 is dependent upon the results for rows B, K and Q. An overlap region 540 at the beginning of a decode pattern includes columns 502, 504, 506; and an overlap region 550 at the ending of a decode pattern includes columns 516, 518, 520. It should be noted that while an overlap of three columns between succeeding local iterations is shown in FIG. 5a, that more or fewer columns may overlap.

As shown in FIG. 5a, processing of column 502 cannot begin in a subsequent local iteration as processing of columns 516, 518 and 520 each impact the same rows processed by column 502 (i.e., row X of columns 502, 516; row A of columns 502, 518; and row B of columns 502, 520). Similarly, processing of column 504 cannot begin in a subsequent local iteration as processing of columns 516 and 520 each impact the same rows processed by column 504 (i.e., row X of columns 504, 516; and row B of columns 504, 520); and processing of column 506 cannot begin in a subsequent local iteration as processing of columns 518 and 520 each impact the same rows processed by column 506 (i.e., row P of columns 506, 518; and row Q of columns 506, 520). Thus, without modifying H-matrix 500, delay cycles sufficient to complete processing of columns 516, 518, 520 must be used to assure that all of the dependencies are resolved.

Returning to FIG. 6, it is determined whether any dependencies exist between the overlap regions (block 620). Where no dependencies exist (block 620), data decoding is performed using the unmodified H-matrix (block 640). Otherwise, where dependencies exist (block 620), other columns that do not exhibit dependencies are identified (block 625). Using FIG. 5a again as an example, none of columns 502, 504, 506 are dependent upon any of columns 512, 514, 516. Accordingly, columns 512, 514, 516 may be chosen as not exhibiting dependencies.

Returning to FIG. 6, the order of the columns exhibiting the aforementioned dependencies may be swapped such that non-dependent columns are used to replace either the columns in the overlap region at the ending or the columns in the overlap region at the beginning (block 630). Thus, using FIG. 5a again as an example, the order of column processing may be modified such that columns 510, 512 and 514 are processed after columns 516, 518, 520. This change is processing order is shown in FIG. 5b where a modified H-matrix 520 is shown, and where overlap region 550 at the ending of a decode pattern now includes columns 516, 518, 520. By making this modification, delay cycles are no longer required to assure proper processing. Returning to FIG. 6, the H-matrix is modified to resolve the dependencies in the overlap regions (block 635), and the modified H-matrix is used to perform decoding (block 640).

Turning to FIG. 8, a flow diagram 800 shows a method in accordance with one or more embodiments for switch limiting during application of a data decoding algorithm. Following flow diagram 800, a first pattern of a Gray code is selected (block 805). The pattern is selected to include columns of an H-matrix that are dependent upon common rows of the H-matrix. . Turning to FIG. 7a as an example, pattern 700 of elements is shown where the columns each rely on different rows (i.e., rows 1-6 on the left side) are included in the same columns (i.e., columns 1-55 along the bottom). Thus, as an example, elements from rows 1, 4 and 6 are connected for the elements of column 1. The rows 1, 4 and 6 corresponds to a Gray code pattern ‘100101’. Each column includes a number of connections that correspond to a given Gray code pattern. Returning to FIG. 8, all of the columns of the H-matrix exhibiting a pattern of row dependencies corresponding to the selected Gray code are identified as a particular pattern set (block 810). Turning to FIG. 7b as an example, a Gray code pattern ‘011001’ is selected and all columns corresponding to this pattern are identified. Pattern set 710 corresponding to Gray code pattern ‘011001’ include columns 10, 16, 24, 32, 38, 42, 44, 46, 50.

It is then determined whether other Gray code patterns remain (block 815). Where other Gray code patterns remain (block 815), a next pattern of the Gray code is selected (block 820) and the processes of blocks 810-815 are repeated for the next Gray code. Turning to FIG. 7c, as an example, pattern set 720 corresponding to a next Gray code pattern ‘101001’ is selected and all columns corresponding to this pattern are identified. Of note, a minimum number of rows changes in the next pattern. In this case, the prior Gray code pattern ‘011001’ is changed to the next Gray code pattern ‘101001’, resulting in a change to only the first two rows. Turning to FIG. 7d, as an example, pattern set 730 corresponding to a next Gray code pattern ‘101010’ is selected and all columns corresponding to this pattern are identified. Of note, a minimum number of rows changes in the next pattern. In this case, the prior Gray code pattern ‘101001’ is changed to the next Gray code pattern ‘101010’, resulting in a change to only the last two rows. Turning to FIG. 7e, as an example, pattern set 740 corresponding to a next Gray code pattern ‘011010’ is selected and all columns corresponding to this pattern are identified. Of note, a minimum number of rows changes in the next pattern. In this case, the prior Gray code pattern ‘101010’ is changed to the next Gray code pattern ‘011010’, resulting in a change to only the first two rows. Turning to FIG. 7f, as an example, pattern set 750 corresponding to a next Gray code pattern ‘010110’ is selected and all columns corresponding to this pattern are identified. Of note, a minimum number of rows changes in the next pattern. In this case, the prior Gray code pattern ‘011010’ is changed to the next Gray code pattern ‘010110’, resulting in a change to only the middle two rows. Turning to FIG. 7g, as an example, pattern set 760 corresponding to a next Gray code pattern ‘010101’ is selected and all columns corresponding to this pattern are identified. Of note, a minimum number of rows changes in the next pattern. In this case, the prior Gray code pattern ‘010110’ is changed to the next Gray code pattern ‘010101’, resulting in a change to only the last two rows. Turning to FIG. 7h, as an example, pattern set 770 corresponding to a next Gray code pattern ‘100101’ is selected and all columns corresponding to this pattern are identified. Of note, a minimum number of rows changes in the next pattern. In this case, the prior Gray code pattern ‘010101’ is changed to the next Gray code pattern ‘100101’, resulting in a change to only the first two rows. Turning to FIG. 7i, as an example, pattern set 780 corresponding to a next Gray code pattern ‘100110’ is selected and all columns corresponding to this pattern are identified. Of note, a minimum number of rows changes in the next pattern. In this case, the prior Gray code pattern ‘100101’ is changed to the next Gray code pattern ‘100110’, resulting in a change to only the last two rows.

Returning to FIG. 8, once it is determined that all of the Gray code patterns have been processed (block 815), the H-matrix is modified to reflect the pattern sets in Gray code order (block 825). Turning to FIG. 7j, the order of the pattern sets 710-780 discussed above in relation to FIGS. 7b-7i corresponding to the Gray code such that switching between rows is limited is shown. With this modified H-matrix, single layer switch limited decoding may be performed (block 830). Using the example of FIG. 7j, pattern set 710 corresponding to Gray code pattern ‘011001’ are processed. Next, pattern set 720 corresponding to Gray code pattern ‘101001’ are processed. Next, pattern set 730 corresponding to Gray code pattern ‘101010’ are processed. Next, pattern set 740 corresponding to Gray code pattern ‘011010’ are processed. Next, pattern set 750 corresponding to Gray code pattern ‘010110’ are processed. Next, pattern set 760 corresponding to Gray code pattern ‘010101’ are processed. Next, pattern set 770 corresponding to Gray code pattern ‘100101’ are processed. Finally, pattern set 780 corresponding to Gray code pattern ‘100110’ are processed.

Turning to FIG. 9, a flow diagram 900 shows a method in accordance with various embodiments of the present invention for a combination of switch limiting and local iteration overlap limiting. Following flow diagram 900, a processing order designed to reduce switching by enforcing a Gray code is applied (block 910). This may be done similar to that discussed above in relation to FIG. 8. Beginning and ending dependencies (i.e., dependencies that occur during succeeding local iterations of a data decoding algorithm) are identified (block 915). This may be done similar to that discussed above in relation to blocks 605-615 of FIG. 6. Where dependencies exist (block 920), an order of the H-matrix is modified to eliminate the dependencies (block 925). Ultimately, the H-matrix, either modified or not, is used to perform the data decoding.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent, albeit such a system would no longer be a circuit. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A system for decoding a data set, the system comprising:
a data decoder circuit operable to apply a data decoding algorithm to a data input to yield a decoded output, wherein operation of the data decoder circuit is governed at least in part by a modified H-matrix; and
wherein the modified H-matrix enforces a column processing order that eliminates dependencies between columns at the beginning of the column processing order and columns at the ending of the column processing order.

2. The system of claim 1, wherein a subsequent local iteration through the data decoder circuit begins before completion of a preceding local iteration through the data decoder circuit.

3. The system of claim 2, wherein the preceding local iteration is performing minimum calculations to yield minimums and minimum locations for a first set of elements while the succeeding local iteration is calculating check node to variable node messages based upon the minimums and minimum locations for a second set of locations.

4. The system of claim 1, wherein the modified H-matrix further enforces a processing order conforming to a Gray code pattern, wherein the Gray code pattern is represented as the row dependencies in each of the columns.

5. The system of claim 1, wherein the system is implemented as part of a device selected from a group consisting of: a storage device, and a communication device.

6. The system of claim 1, wherein the data decoder circuit implements a low density parity check decoding algorithm.

7. The system of claim 1, wherein the system is implemented as part of an integrated circuit.

8. The system of claim 1, wherein the modified H-matrix includes columns of circulants in an order that reduces switching between rows in the modified H-matrix.

9. A system for decoding a data set, the system comprising:
a data decoder circuit operable to apply a data decoding algorithm to a data input to yield a decoded output, wherein operation of the data decoder circuit is governed at least in part by a modified H-matrix; and
wherein the modified H-matrix enforces a column processing order that processes H-matrix columns in an order according to column row dependencies.

10. The system of claim 9, wherein the column row dependencies include at least a first set of column row dependencies, a second set of column row dependencies, a third set of column row dependencies, and a fourth set of column row dependencies; and wherein the column processing order includes: processing all columns exhibiting the first set of column row dependencies before processing all columns exhibiting the second set of column row dependencies, processing all columns exhibiting the second set of column row dependencies before processing all columns exhibiting the third set of column row dependencies, and processing all columns exhibiting the third set of column row dependencies before processing all columns exhibiting the fourth set of column row dependencies.

11. The system of claim 10, wherein switching from rows in the first set of column row dependencies and the second set of column row dependencies, from rows in the second set of column row dependencies and the third set of column row dependencies, from rows in the third set of column row dependencies and the fourth set of column row dependencies, and from rows in the third set of column row dependencies and the fourth set of column row dependencies corresponds to a Gray code pattern of the rows.

12. The system of claim 11, wherein the Gray code pattern of the rows limits switching between rows of the modified H-matrix during application of the data decoding algorithm.

13. The system of claim 12, wherein limiting switching between rows during application of the data decoding algorithm reduces power consumption by the data decoder circuit.

14. The system of claim 9, wherein the modified H-matrix further enforces a column processing order that eliminates dependencies between columns at the beginning of the column processing order and columns at the ending of the column processing order.

15. The system of claim 9, wherein the system is implemented as part of a device selected from a group consisting of: a storage device, and a communication device.

16. A method for decoding a data set, the method comprising:
providing a data decoder circuit operable to apply a data decoding algorithm to a data input to yield a decoded output; and
applying the data decoding algorithm guided by a modified H-matrix, wherein the modified H-matrix enforces a column processing order that eliminates dependencies between columns at the beginning of the column processing order and columns at the ending of the column processing order.

17. The method of claim 16, wherein the modified H-matrix further enforces a column processing order that processes H-matrix columns in an order according to column row dependencies.

18. The method of claim 17, wherein the column row dependencies include at least a first set of column row dependencies, a second set of column row dependencies, a third set of column row dependencies, and a fourth set of column row dependencies; and wherein the column processing order includes: processing all columns exhibiting the first set of column row dependencies before processing all columns exhibiting the second set of column row dependencies, processing all columns exhibiting the second set of column row dependencies before processing all columns exhibiting the third set of column row dependencies, and processing all columns exhibiting the third set of column row dependencies before processing all columns exhibiting the fourth set of column row dependencies.

19. The method of claim 18, wherein switching from rows in the first set of column row dependencies and the second set of column row dependencies, from rows in the second set of column row dependencies and the third set of column row dependencies, from rows in the third set of column row dependencies and the fourth set of column row dependencies, and from rows in the third set of column row dependencies and the fourth set of column row dependencies corresponds to a Gray code pattern of the rows.

20. The method of claim 19, wherein the Gray code pattern of the rows limits switching between rows of the modified H-matrix during application of the data decoding algorithm.
